(19) United States
(12) Patent Application Publication
(10) Pub. No.: US 2011/0101534 A1
(43) Pub. Date: May 5, 2011

(54) AUTOMATED SHORT LENGTH WIRE SHAPE STRAPPING AND METHODS OF FABRICTING THE SAME

(75) Inventor: Anthony K. STAMPER, Williston, VT (US)

(73) Assignee: INTERNATIONAL BUSINESS MACHINES CORPORATION, Armonk, NY (US)

(21) Appl. No.: 12/612,160

(22) Filed: Nov. 4, 2009

(51) Int. Cl. H01L 23/522; H01L 21/768

(52) U.S. Cl. 257/773; 438/622; 257/E23.142; 257/E21.575

(57) ABSTRACT

An automatic short length wire shape generation and strapping and method of fabricating such wires is provided. The method of manufacturing includes breaking of a wiring into adjacent short length wires which are below a maximum short length effect length. The adjacent short length wires are formed in a same wiring level of an integrated circuit. The method further includes forming a conductive strap in a single deposition process which overlaps and is in contact with the adjacent short length wires.

### FIELD OF THE INVENTION

The invention relates to integrated circuits and methods of manufacturing, and more particularly, to automatic short length wire shape generation and strapping and methods of fabricating such wires.

### BACKGROUND

The reliability of interconnections in microelectronic circuits is generally limited by a phenomenon known as electromigration. For example, as microelectronic circuits are made more dense in order to improve performance, the electric fields and resulting current densities in the interconnects increase. However, as circuit densities increase, the rate of electromigration also increases.

Electromigration leads to circuit failure primarily via two mechanisms. In the first mechanism, the primary conductor, which typically is aluminum or copper, electromigrates away from a region in the interconnect faster than the availability of additional atoms can take its place. This process generates a void in the interconnection, and growth of the void increases the electrical resistance of the interconnection such that circuit failure occurs. In the second mechanism, electromigration failure occurs when metal electromigrates into a region faster than it escapes the region, thus locally piling up metal atoms to a point where it extends to the adjacent interconnection line, thereby causing an electrical short circuit.

The problem of electromigration has been approached in a number of ways. By way of example, the two most common ways to approach electromigration include introducing a second species into the parent metal or utilizing a redundant metal layer under and/or over the aluminum lines. While the above methods increase electromigration lifetime, it has been found that electromigration failure cannot be totally avoided because void growth cannot completely be suppressed, i.e., void sizes increase with time. So, for example, redundant layers can extend the electromigration lifetime of metal lines, but void growth is not completely eliminated.

The electromigration lifetime increases dramatically for short length wires, due to back pressure primary conductor vacancy generation in short length wires. The short-length effect takes place in short interconnections if an electrical current is supplied through leads of materials in which diffusivity is low. The physical origin of the short-length effect is the build-up of backstress as aluminum atoms pile up against the diffusion barrier leads. This backstress counteracts the electromigration driving force. A steady-state condition arises in situations where the backstress exactly balances the electromigration driving force. Under this condition, no further electromigration damage results.

The existence of the short-length effect has been demonstrated previously and is not a new phenomenon. However, the design of short interconnect wires is not a trivial task. For example, current technology includes fabricating complex interconnect structures that include jogs and other complex shapes, which add to the length of the interconnect between wires as well as processing costs. The complex shapes include the formation of vias extending entirely through a dielectric layer to underlying wiring and additional wiring that connects the vias together. The formation of the vias and the additional wires is a complex fabrication process that includes etching vias and trenches using, for example, damascene processes, then deposition of metal in vias and trenches within the dielectric. These complex shapes also have to be carefully designed to ensure that they do not interfere with other devices on the integrated circuit.

Accordingly, there exists a need in the art to overcome the deficiencies and limitations described hereinabove.

### SUMMARY

In an aspect of the invention, a method of manufacturing a structure comprises forming adjacent short length wires in a same wiring level of an integrated circuit separated by an insulator material. A combination of the adjacent short length wires are below a maximum short length effect length. The method further comprises forming a conductive strap in a single deposition process which overlaps and is in contact with the adjacent short length wires.

In an aspect of the invention, a method of manufacturing a structure comprises breaking of a wiring into adjacent short length wires which are below a maximum short length effect length. The adjacent short length wires are formed in a same wiring level of an integrated circuit. The method further comprises forming a conductive strap in a single deposition process which overlaps and is in contact with the adjacent short length wires.

In an aspect of the invention, a structure comprises adjacent wires in a same wiring level of an integrated circuit separated by an insulator material. The adjacent wires are below a maximum short length effect length. A conductive strap is entirely within a same plane as the adjacent wires and is in contact with the adjacent wires. The conductive strap extends only partially within a dielectric layer above or below the adjacent wires.

In another aspect of the invention, a design structure embodied in a machine readable medium for designing, manufacturing, or testing an integrated circuit is provided. The design structure comprises the structures and/or methods of the present invention.

### BRIEF DESCRIPTION OF THE SEVERAL VIEWS OF THE DRAWINGS

The present invention is described in the detailed description which follows, in reference to the noted plurality of drawings by way of non-limiting examples of exemplary embodiments of the present invention.

FIGS. 1-3 show structures and respective processing steps in accordance with aspects of the invention;

FIGS. 4 and 5 show an alternative structure and respective processing steps in accordance with another aspect of the invention; and

FIG. 6 shows a flow diagram of a design process used in semiconductor design, manufacture, and/or test.

### DETAILED DESCRIPTION

The invention relates to integrated circuits and methods of manufacturing, and more particularly, to automatic short length wire shape generation and strapping and methods of fabricating such wires. In implementation, the invention includes conductive straps above or below wiring in order to break up or reduce the length of the wires. The straps, for example, can be made from any conductive material and are designed and structured to be in a single plane, deposited either in or above a single dielectric layer. The straps will contact the wiring such that the length of the wires can be reduced to take advantage of the short length effect. The straps will also effectively eliminate the complex wiring interconnect structures currently in use which include wiring structures having jogs and other complex shapes that extend between wiring below or above the complex wiring interconnect structures.

The present invention will thus effectively shorten the desired portion up to and including the entire wiring structure (e.g., wiring and interconnect structure), while reducing the need for complex shapes and additional and expensive manufacturing processes. Also, advantageously, the use of the conductive straps of the present invention can be placed anywhere on the integrated circuit in an automated fashion, and increase electromigration lifetime of the device without the need for any custom designs.

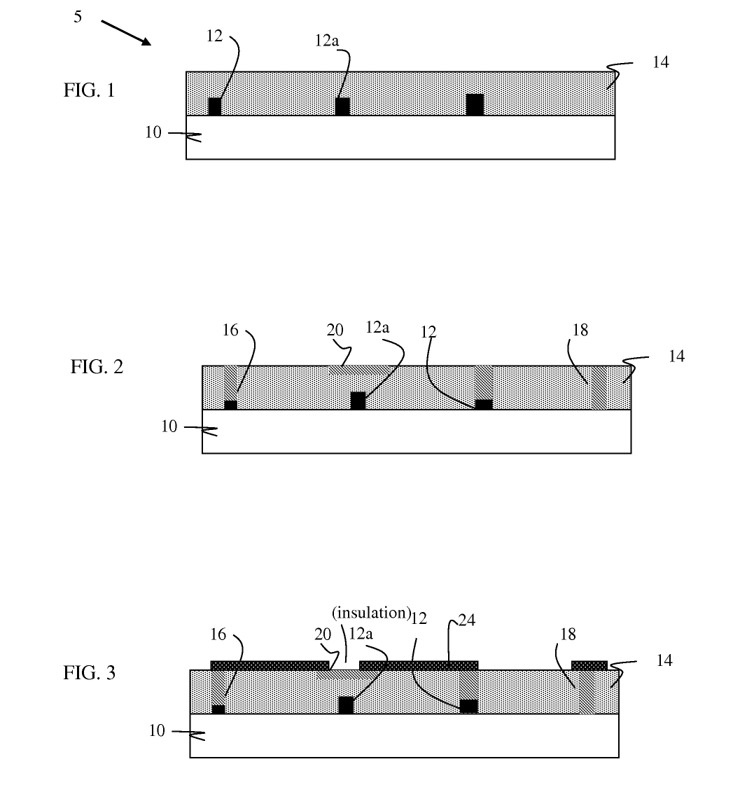

FIG. 1 shows a beginning structure in accordance with an aspect of the invention. In particular, the structure 5 comprising a substrate 10 such as, for example, silicon, SOI, SiGe, quartz, sapphire, glass or Gallium arsenide, to name a few. In embodiments, the remaining structure can be manufactured using many different processes steps. For example, in one optional embodiment, transistor gates or other active or passive devices 12 can be formed on the substrate 10 using conventional formation processes known to those of skill in the art such that further explanation is not required herein for an understanding of the invention.

In embodiments, a stud connector (e.g., structure) 12a can also be formed on the substrate using conventional deposition processes. The stud connector 12a can be, for example, a tungsten or copper stud formed by a metal sputtering process, and configured to be connected to underlying wires (not shown), e.g., an underlying gate, or active or passive device.

Still referring to FIG. 1, a dielectric layer 14 can be deposited on the substrate 10 and over the transistor gate or other devices 12 and stud connector 12a. The dielectric layer 14 can be, for example, SiO₂; although, other dielectric materials are also contemplated by the invention. The dielectric layer 14 could be deposited using any known method, such as plasma-enhanced chemical vapor deposition (PECVD). In embodiments, the stud connector 12a will be at a minimum height, e.g., shallow, within the dielectric layer 14 in order to ensure that future wiring layers will not short to the stud connector 12a and hence to an underlying gate, active or passive device.

In alternative embodiments, the stud connector 12a can be formed after the deposition of a first layer of the dielectric layer 14 (e.g., deposited to a height of a stud connector 12a to be formed therein) using conventional lithographic, etching and metal deposition techniques known to those of skill in the art. For example, a photoresist can be deposited on a first layer of the dielectric layer 14 and exposed to light to form an opening. A reactive ion etching (RIE) can then be performed to open a via in the dielectric layer 14, in alignment with the underlying wiring (underlying gate, active or passive device). A metal deposition and damascene process can then be performed to form the stud connector 12a. Additional dielectric layer 14 can then be deposited on the first layer of dielectric material.

In FIG. 2, the dielectric layer 14 is subject to a lithographic and etching process in order to open holes and form metal studs 16 in contact with the transistor gate or other devices 12 (or 12a). In further embodiments, metal studs 18 can be formed in the same processing steps, to the substrate 10. The metal studs 16 and 18 (and perhaps another stud contacting structure 12a, in certain embodiments) can be formed using conventional metal deposition and damascene processes such as, for example, metal sputtering techniques. In embodiments, the metal studs 16 and 18 are preferably tungsten with a TiN liner as known in the art, but any metal or metal alloy is contemplated by the invention such as, for example, copper Ta, TaN, etc. In embodiments, the structures on the substrate 12 and 12a will be about one quarter the height of the metal studs 16; although other heights are also contemplated by the invention, with the understanding that the height of structures 12 and 12a will be set to ensure that the structures 12 and 12a will not short with a wiring formed below the stud connector 12a. For example, in embodiments, the structures 12 and 12a is approximately one quarter the height of the metal studs 16.

Still referring to FIG. 2, the dielectric layer 14 can be lithographically patterned and etched to form a shallow trench over the stud connector 12a. The shallow trench should preferably be etched to such a depth that dielectric material will remain over the elements 12 and 12a. This will ensure that shorting will not occur between wiring layers, for example. The trench is then filled with a thin layer of metal to form a strap 20, i.e., thin wire that is placed under yet to be formed short length wires. In embodiments, the strap 20 is about 30 nm in thickness (although other dimensions are also contemplated by the invention) and is deposited in a single deposition process to a thickness (e.g., thin layer) that avoids shorting to, for example, MOSFET PC conductors or other underlying devices or wires. In this way, the strap 20 could be placed anywhere on the integrated circuit in an automated fashion. The strap 20 can be any known metal used for connecting short wires such as, for example, Ta, W, TaN, NiCr, etc., and can be formed as a contact bar (CABAR).

In embodiments, the strap 20 and the metal studs 16, 20 can be processed concurrently using a dual damascene process. In the dual damascene process, trenches for both the strap 20 and the metal studs 16, 20 are formed in two etching processes. Once formed, metal is deposited in the trenches to form the strap 20 and the metal studs 16, 20. In either embodiment, after the deposition of the metal is completed (e.g., forming the strap 20 and the metal studs 16, 20), the structure undergoes a chemical mechanical polish (CMP) in order to planarize the structure of FIG. 2.

In FIG. 3, a dielectric layer 22 is deposited over the structure of FIG. 2. For example, the dielectric layer 22 is deposited over the strap 20 and the metal studs 16, 18 and exposed portions of the dielectric layer 14. Short wires 24 are then formed in contact with the strap 20 in the dielectric layer 22 using conventional damascene processes. For example, the short wires 24 may be TaN lined copper formed using conventional damascene processes such as, for example, lithographic, etching and deposition processes known to those of skill in the art. The dimensions of the short wires 24 will be a length which takes advantage of the short length effect. The short wire length effect is a function of the initial vacancy of the wire. The initial vacancy of the wire is determined by the length width and height, as well as its elemental composition, as is well known art. For example, in a 90 nm ground rule technology, the short wires can be length (L) of about 10 μm to about 100 μm and width (W) of about greater than or equal to 90 nm; although other dimensions are contemplated by the invention which are below a below a maximum short length effect length. In this way, therefore, the electromigration lifetime in the electrical path will be increased.

In embodiments, the short wires 24 are formed in contact with the metal studs 16, 18 and the strap 20. The strap 20, in embodiments, is the same width as the adjacent short wires 24. The spacing between the adjacent short wires 24 may be the minimum allowable ground rule for a particular node, e.g., a spacing of 90 nm for a 90 nm node. The overlap between the short wires 24 and the strap 20 should provide good contact and, in embodiments, would be the minimal ground rule. As an example, for a 90 nm node, the overlap would be about 90 nm or greater. The present invention, though, contemplates that other overlap lengths can be provided, depending on the technology ground rules.

Advantageously, in any embodiment, the strap 20 can be placed at any location on the IC since it is a thin wire placed directly in contact with short wires 24, in a same orientation, e.g., without a complex shape extending or designed in two or more planes. That is, the strap 20 is entirely in the same plane as the short wires 24. Also, as the strap 20 occupies only a single plane (e.g., it only is deposited in a trench, and not within a via and a trench), it will not interfere with other devices or wiring on the IC and, in an automated fashion, it is possible to determine the required location/placement of the strap 20 based on the location of the of the short wires 24 and the distance separating the short wires 24.

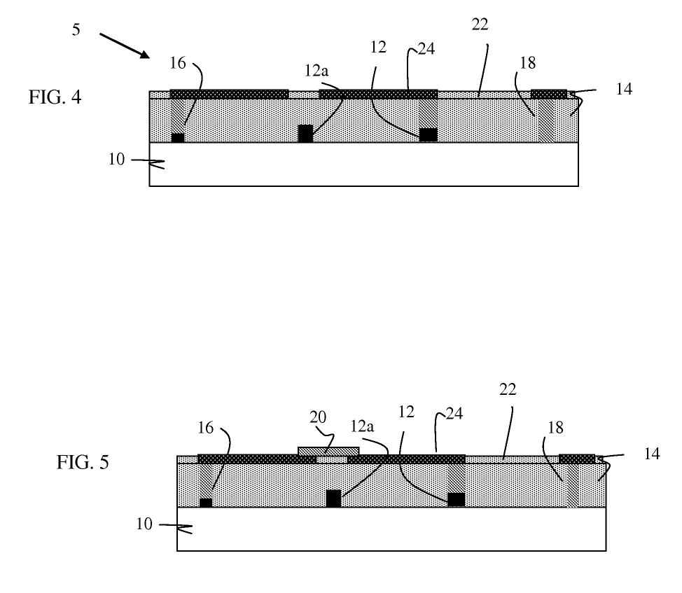

FIGS. 4 and 5 show alternative embodiments in accordance with the invention. More specifically, referring to FIG. 4, the structure 5 comprising a substrate 10 such as, for example, silicon, SOI, SiGe, quartz, sapphire, glass or Gallium arsenide, to name a few. In one optional embodiment, structures 12 and 12a, as discussed supra, can be formed on the substrate 10.

Still referring to FIG. 4, a dielectric layer 14 can be deposited on the substrate 10 and over the transistor gate or other structures 12 and 12a. The dielectric layer 14 can be, for example, SiO₂; although, other dielectric materials are also contemplated by the invention. The dielectric layer 14 could be deposited using any known method, such as plasma-enhanced chemical vapor deposition (PECVD). In embodiments, the stud connector 12a will be at a minimum height, e.g., shallow, within the dielectric layer 14 in order to ensure that future wiring layers will not short to the structures 12 and 12a and hence to an underlying gate, active or passive device. In alternative embodiments, the structure 12a can be formed after the deposition of a first layer of the dielectric layer 14 (e.g., deposited to a height of a structure 12a to be formed therein) using conventional lithographic, etching and metal deposition techniques as described above.

In FIG. 4, the dielectric layer 14 is subject to a lithographic and etching process in order to open holes and deposit metal studs 16 and 18 in contact with the transistor gate or other devices 12. The metal studs 16 and 18 are preferably TiN lines tungsten, as known in the art, but any metal or metal alloy is contemplated by the invention such as, for example, copper Ta, TaN, etc. In embodiments, the stud connector 12a will be about one quarter the height of the metal studs 16 (and/or 18); although other heights are also contemplated by the invention, with the understanding that the height of the stud connector 12a will be set to ensure that the stud connector 12a will not short with a wiring formed above and below the stud connector 12a. The metal studs 16 can be deposited using conventional metal deposition processes such as, for example, metal sputtering techniques.

Still referring to FIG. 4, a dielectric layer 22 is deposited over the structure of FIG. 2. For example, the dielectric layer 22 is deposited over the metal studs 16, 18 and exposed portions of the dielectric layer 14. Short wires 24 are then formed in the dielectric layer 22 using conventional deposition processes. For example, the short wires 24 may be TaN lined copper formed using conventional damascene processes such as, for example, lithographic, etching and deposition processes known to those of skill in the art. The dimensions of the short wires 24 will be a length which take advantage of the short length effect as described above.

In one embodiment, the short wires 24 can be fabricated using subtractive etch processes, as discussed supra. In another embodiment, the short wires 24 can be formed as a single layer, with a portion etched away to form the two short wires. The space between the adjacent short wires 24 can then be filled with an oxide or other insulator material to form a shallow trench isolation structure (STI). The spacing between the adjacent short wires 24 may be the minimum allowable ground rule for a particular node, e.g., a spacing of 90 nm for a 90 nm node, and are below a below a maximum short length effect length. In any of these embodiments, short wires 24 can optionally undergo a chemical mechanical polish (CMP).

Referring to FIG. 5, a strap 20, i.e., thin wire level, is deposited in contact with the adjacent short wires 24. In embodiments, the strap 20 overlaps between the short wires 24 on each side as discussed above. The present invention, though, contemplates that may different overlap lengths can be provided, depending on the technology ground rules. The strap 20 can be formed by subtractive etching techniques, known to those of skill in the art.

In embodiments, the strap 20 is about 30 nm in thickness (although other dimensions are also contemplated by the invention) and is thin enough to avoid shorting to, for example, MOSFET PC conductors or other devices or wires formed above the strap 20. In this way, the strap 20 could be placed anywhere on the integrated circuit in an automated fashion. The strap 20 can be any known metal used for connecting short wires are refractory metals such as, for example, Ta, W, TaN, NiCr, etc.

In embodiments, the strap 20 can be formed in manner different ways. However, advantageously, the strap 20 can be deposited in a single deposition process as discussed above. For example, metal can be placed over the short length wires 24, patterned and etched without damaging the adjacent short wires 24. In another embodiment, the strap 20 can be formed as a contact bar (CABAR) or a VIABAR over the dielectric layer 22. The VIABAR, for example, can be fabricated using a damascene process in upper wiring layers. In yet another embodiment, a dielectric layer (not shown) can be deposited over the strap 20 to form additional wiring layers.

Again, in any of the embodiments shown in FIGS. 4 and 5, advantageously the strap 20 can be placed at any location on the IC directly in contact with short wires 24, in a same orientation (e.g., single plane). That is, the strap 20 will not have a complex shape, e.g., jogs formed in vias extending from the short wires and other portions extend between the vias. Also, as the strap 20 is a thin wire extending in a single plane, it will not interfere with other devices or wiring on the IC and, in an automated fashion, it is possible to determine the required location/placement of the strap 20 based on the location of the of the short wires 24 and the distance separating the short wires 24.

In any of the embodiments, the wires (e.g., copper wires) are broken up into short wire lengths in an automated fashion where the short wire lengths are connected using automatically generated thin wiring which is placed in contact over (or under) the short wires 24. For example, the designer designs the short wires 24 with a short tag length such that the shapes of the straps 20 are automatically added and the M1 wires (e.g., short wires 24) are automatically broken up into multiple wires.

### Design Structure

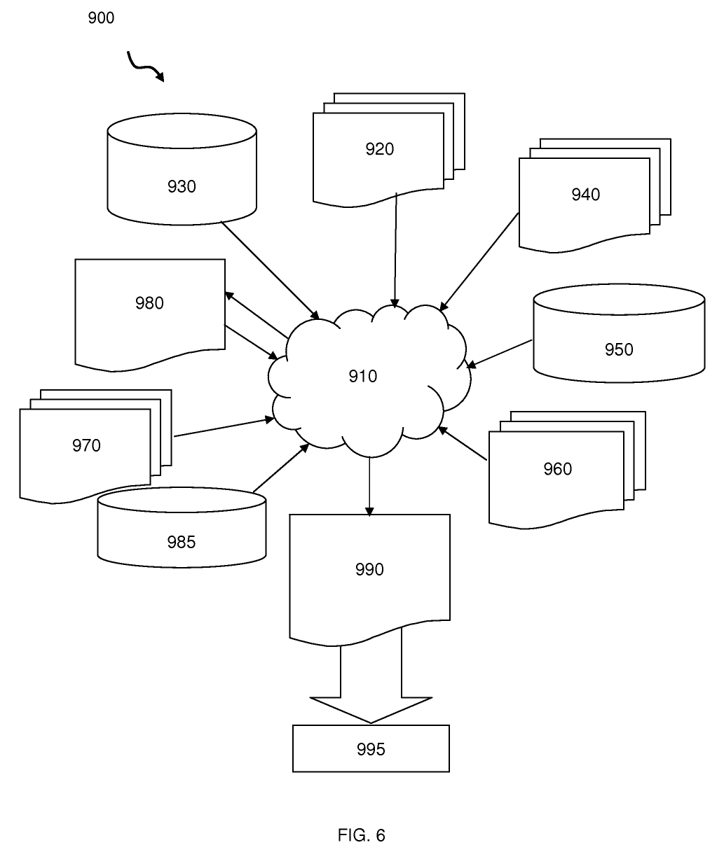

FIG. 6 illustrates multiple such design structures including an input design structure 920 that is preferably processed by a design process 910. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD) such as implemented by a core developer/designer. When encoded on a machine-readable data transmission, gate array, or storage medium, design structure 920 may be accessed and processed by one or more hardware and/or software modules within design process 910 to simulate or otherwise functionally represent an electronic component, circuit, electronic or logic module, apparatus, device, or system such as those shown in FIGS. 1-5. As such, design structure 920 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 910 preferably employs and incorporates hardware and/or software modules for synthesizing, translating, or otherwise processing a design/simulation functional equivalent of the components, circuits, devices, or logic structures shown in FIGS. 1-5 to generate a netlist 980 which may contain design structures such as design structure 920. Netlist 980 may comprise, for example, compiled or otherwise processed data structures representing a list of wires, discrete components, logic gates, control circuits, I/O devices, models, etc. that describes the connections to other elements and circuits in an integrated circuit design. Netlist 980 may be synthesized using an iterative process in which netlist 980 is resynthesized one or more times depending on design specifications and parameters for the device. As with other design structure types described herein, netlist 980 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 910 may include hardware and software modules for processing a variety of input data structure types including netlist 980. Such data structure types may reside, for example, within library elements 930 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 940, characterization data 950, verification data 960, design rules 970, and test data files 985 which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of the invention. Design process 91Q may also include modules for performing standard circuit design processes such as timing analysis, verification, design rule checking, place and route operations, etc.

Design process 910 employs and incorporates logic and physical design tools such as HDL compilers and simulation model build tools to process design structure 920 together with some or all of the depicted supporting data structures along with any additional mechanical design or data (if applicable), to generate a second design structure 990. Design structure 990 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures). Similar to design structure 920, design structure 990 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-5. In one embodiment, design structure 990 may comprise a compiled, executable HDL simulation model that functionally simulates the devices shown in FIGS. 1-5.

Design structure 990 may also employ a data format used for the exchange of layout data of integrated circuits and/or symbolic data format (e.g. information stored in a GDSII (GDS2), GL1, OASIS, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-5. Design structure 990 may then proceed to a stage 995 where, for example, design structure 990: proceeds to tape-out, is released to manufacturing, is released to a mask house, is sent to another design house, is sent back to the customer, etc.

The methods as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A method of manufacturing a structure, comprising:
breaking of a single wiring into adjacent short length wires which are below a maximum length, the adjacent short length wires being in a same wiring level of an integrated circuit; and
forming a conductive strap which overlaps and is in contact with the adjacent short length wires.

2. The method of claim 1, wherein the conductive strap is an automatically generated thin wiring which is formed entirely in a single plane.

3. The method of claim 2, wherein the conductive strap is formed in the dielectric material below the adjacent short length wires.

4. The method of claim 3, wherein the conductive strap is deposited above a conductive stud and separated from the conductive stud by dielectric material.

5. The method of claim 2, wherein the conductive strap is deposited over the adjacent short length wires.

6. The method of claim 2, wherein the conductive strap is formed partially though a layer of the dielectric material.

7. The method of claim 2, wherein the conductive strap is formed with a subtractive etching process.

8. The method of claim 2, wherein the adjacent short length wires are formed with a subtractive etching process.

9. The method of claim 1, wherein the overlap provides contact with each side of the conductive strap and the adjacent short length wires.

10. The method of claim 1, wherein the adjacent short length wires are formed in contact with the conductive strap by depositing metal above the conductive strap.

11. The method of claim 1, wherein the conductive strap is automatically generated based on a location of the adjacent short length wires.

12. A method of manufacturing a structure, comprising:
forming adjacent wires in a same wiring level of an integrated circuit separated by an insulator material, the adjacent wires are below a maximum short length effect; and
forming a conductive strap entirely within a single plane and which overlaps and is in contact with the adjacent wires.

13. The method of claim 12, wherein the conductive strap is a thin metal film formed in a shallow trench above a conductive stud and separated from the conductive stud by dielectric material.

14. The method of claim 12, wherein the conductive strap is formed in a dielectric material below the adjacent wires, by etching a shallow trench in the dielectric material and depositing a metal in the shallow trench such that the conductive strap extends only partially within the dielectric material.

15. The method of claim 12, wherein the conductive strap is below the adjacent wires.

16. The method of claim 12, wherein the conductive strap is deposited over the adjacent wires in a different wiring level than the adjacent wires.

17. The method of claim 12, wherein the conductive strap is automatically generated based on a location of the adjacent wires.

18. A structure, comprising:
adjacent wires in a same wiring level of an integrated circuit separated by an insulator material, a combination of which are below a maximum short length effect length; and
a conductive strap entirely within a single plane and which is in contact with the adjacent wires, wherein the conductive strap will extend only partially within a dielectric layer above or below the adjacent wires, wherein the conductive strap overlaps with the adjacent wires.

19. The structure of claim 18, wherein the conductive strap is above the adjacent wires.

20. The structure of claim 18, wherein the conductive strap is below the adjacent wires.
